(19) United States
(12) Patent Application Publication
(10) Pub. No.: US 2004/0147070 A1
(43) Pub. Date: Jul. 29, 2004

(54) Ultra-shallow junction formation for nano MOS devices using amorphous-si capping layer

(75) Inventors: Tan Fu Lei, Hsinchu (TW); Tzu Yun Chang, Hsinchu Hsien (TW); Huang-Chun Wen, Tainan City (TW)

Correspondence Address: BACON & THOMAS, PLLC, 625 SLATERS LANE, FOURTH FLOOR, ALEXANDRIA, VA, 22314

(73) Assignee: NATIONAL CHIAO-TUNG UNIVERSITY, Hsinchu City (TW)

(21) Appl. No.: 10/349,967

(22) Filed: Jan. 24, 2003

(51) Int. Cl. H01L 21/8238

(52) U.S. Cl. 438/199

(57) ABSTRACT

The present invention provides a new ultra-shallow junction formation method for nano-MOS technology applications by using conventional ion implantation and rapid thermal annealing techniques without requirement of low energy implant equipments to fabricate ultra-shallow junctions. Diffusion from implanted amorphous silicon (DIA) is performed by junction implant through an amorphous capping layer; the amorphous layer thus acts as a surface solid diffusion source during annealing. A thin oxide is deposited to serve as etching stop layer beneath the amorphous layer. This bilayer amorphous-oxide structure enables easy removal of the amorphous layer and provides good process control and device reliability. By using amorphous silicon layer as the diffusion source for junction formation, implant defects are reduced. Defect-free ultra-shallow junctions can be formed.

### FIELD OF THE INVENTION

The present invention relates to a manufacturing process for standard CMOSFET, and more particularly to an ultra-shallow junction formation for nano MOS devices.

### BACKGROUND OF THE INVENTION

The IC fabrication industry has always required the scaling of MOSFET devices to increase the density and speed of digital ICs. Scaling the device channel length and width can increase the density of ICs. And the MOSFET saturation drain current must be increased for faster speed. Technology improvements over these 35 years have followed the “Moore's law” stating that the number of transistors on a chip doubles every three years. However, as devices are scaled to gate lengths smaller than 1 μm, MOSFETs began to exhibit other phenomena unlike long-channel MOSFET models. Short channel effects occur in devices with gate lengths smaller than 0.5 μm, when the drain current in saturation I_{DSAT} shows less increase as gate length is decreased. In extremely small MOSFETS, I_{DSAT} are predicted to be independent of gate length, and scaling the oxide thickness became the most efficient measure in the demand of larger MOSFET saturation currents.

Today's MOS device structures will begin to encounter significant problems, lateral device dimensions smaller than 0.05 μm require very thin gate oxides. Gate oxides cannot be shrunk below 1-1.5 nm because electrons can easily tunnel through such thin insulators. And also at such dimensions, it is difficult to keep PN junctions from interacting with each other.

Innovations in device and fabrication must be presented in order to continue scaling dimensions in integrated circuits for the technology to progress beyond the ITRS (International Technology Roadmap of Semiconductors).

The continuous scaling of CMOS devices has produced a series of difficult challenges to the processes used to form the active layers in deep sub-micron transistors, Two major requirements in the downsizing of MOSFETs are the suppression of “off” state leakage currents, and low resistance for a high current drive in the “on” state. In small gate lengths even when the device is in the “off” state, a leakage current from the drain to the source is observed due to the lowering of the threshold voltage VT as gate length is decreased. The space charge region near the drain may also touch the source somewhere deeper in the substrate where the gate bias cannot control the potential and punch through occurs at smaller drain biases. The off current is a key design parameter and can be minimized by keeping the junctions shallow.

In the “on” state, reduction of the gate length is desirable because it decreases the channel resistance of the MOSFET. However, when the channel resistance becomes as small as the source and drain resistance, high activation levels of dopants are demanded to reduce parasitic resistances of the source/drain and extension regions. The diffusion cycles required to electrically activate the implanted dopant atoms are often the limiting factor of the junction depth. These conflicting issues are the main criteria in research of ultra-shallow junctions.

Formation of Ultra-Shallow Junctions

The formation of ultra shallow junctions has become a significant challenge in device scaling. Ultra-low thermal budgets will be required to limit diffusion at the expense of activating dopants and removing process damage. Shallow junction must also have low resistance contacts. Producing highly doped and fully activated shallow junctions will be needed. The most serious of these requirements is the junction depth of the “Source/Drain Extension”. For the present 100 nm processes, junctions in the order of 20-40 nm are required.

The conventional approach, ion implantation at a low energy followed by a RTA (Rapid Thermal Annealing) step, gives reproducible shallow junctions. However, the ion implantation technique causes damage to the silicon crystal and annealing must be conducted at high temperatures. It is also subjected to the channeling effect of dopants while thermal diffusion, transient enhanced diffusion (TED), boron enhanced diffusion and oxidation enhanced diffusion drive dopants deeper during thermal processing. Many tactics, such as the control of anneal ambient, reducing the thermal budget by spike anneals and high ramp up/down rates have been proposed to implement shallow junctions. Though temporary solutions, rapid thermal process (RTP) still faces the problem of low activation limited by solid solubility.

Other Methods to Fabricate Ultra-Shallow Junctions

An alternative implant technique is by plasma doping (PLAD) and plasma immersion ion implantation (PIII). Plasma doping is advantageous due to its easy-to-control, high throughput, low implant energies and low cost. However, the wafer is placed in the plasma source directly applying the acceleration bias. Therefore, all ionized gas species are accelerated into the wafer, while chamber contaminants could also be implanted. Other potential doping solutions include, projection gas immersion doping (PGILD), rapid vapor phase doping (RVD), and rapid thermal gas immersion doping.

To control the channeling of dopants during implantation, preamorphizing the silicon surface prior to junction implantation using non-active species (usually from group IV) has been shown to exhibit shallow junction depths. However, the additional implantation itself could introduce end-of-range defects, forming a zone of interstitial dislocation loops near the amorphous-crystalline interface. It is difficult to completely anneal out the damage produced by the high dose amorphizing implantation. Additional defects will also enhance the TED effect.

Shallow junctions can also be formed by out diffusion, either from doped oxides such as PSG and BSG, or from the gas phase. Though overcoming the above-mentioned problems of ion implantation, out diffusion generally introduces a large spread on sheet resistance and junction depth.

The Laser Thermal Process (LTP) has been a potential replacement of RTP for dopant activation for its ability of a zero thermal budget, local selective heating, and without the restraint of solid solubility. LTP is not yet suitable for production due to its low throughput and uniformity.

### SUMMARY OF THE INVENTION

Therefore, the present invention provides a junction formation method by using conventional ion implantation and rapid thermal annealing techniques without requirement of low energy implant equipments to fabricate

The concept of diffusion from implanted amorphous (DIA) method is to form a surface solid diffusion source and remove this screening layer after diffusion.

First, a thin oxide is deposited to serve as etching stop layer and a highly doped amorphous silicon layer is formed by ion implantation. In a subsequent RTA step, the dopant diffuses into the underlying silicon to form a p-n junction. Both layers are removed by wet etching after junction formation. This bilayer amorphous-oxide structure enable easy removal of the amorphous layer which provides good process control and device reliability.

By using amorphous silicon layer as the diffusion source for junction formation, implant defects are reduced. Defect-free ultra-shallow junctions can be fabricated.

### BRIEF DESCRIPTION OF THE DRAWINGS

FIG. 1 shows schematically the method of DIA (Diffusion from Implanted Amorphous Silicon).

FIG. 2 shows the process flow of DIA formation.

Table 1 is an RTA condition table for experiment A.

FIG. 3 shows Boron Secondary Ion Mass Spectroscopy (SIMS) profiles for experiment A.

Table 2 shows the sheet resistance results for experiment A.

Table 3 is the RTA time and temperature condition table for experiment B.

FIG. 4 shows the as-implemented boron SIMS profile for DIA.

FIG. 5 shows the sheet resistance change as RTA time and temperature increases for 40 keV BF₂⁺ implant sample.

FIG. 6 shows the sheet resistance change as RTA time and temperature increases for 45 keV BF₂⁺ implant sample.

FIG. 7 shows the sheet resistance change as RTA time and temperature increases for 50 keV BF₂⁺ implant sample.

FIG. 8 shows boron SIMS profile of various boron implant energies after RTA 900° C. for 25 second.

FIG. 9 shows boron SIMS profile of various boron implant energies after RTA 1000° C. for 5 second.

FIG. 10 shows boron SIMS profile of various boron implant energies after RTA 1000° C. for 10 second.

FIG. 11 shows boron SIMS profile of various boron implant energies for as-implanted and samples after 1000° C. 5 s RTA.

Table 4 shows the Junction depth relation with implant energy and RTA condition for experiment B.

FIG. 12 shows the cumulative plot of junction leakage current density measured at reverse voltage 3V for DIA junction with RTA 1050° C. 5 s at various implant energies.

FIG. 13 shows the cumulative plot of junction leakage current density measured at reverse voltage 3V for DIA junction with RTA 1000° C. 5 s at various implant energies.

FIG. 14 shows the reverse current-voltage characteristics of 50 keV, RTA condition 1000° C. 5 s sample measured at various temperatures.

FIG. 15 is the schematic illustration of leakage components in a reverse junction.

FIG. 16 shows schematically that the junction leakage current I_{R} is the sum of the peripheral current I_{RP} and the area current I_{RA}.

FIG. 17 shows that the reverse leakage current density is plotted as a function of P/A ratio.

FIG. 18 shows the reverse junction leakage current density vs. periphery to area ratio (P/A ratio) for RTA condition of 1050° C. 5 s.

FIG. 19 shows the Arrhenius plot of the reverse current versus 1/kT.

FIG. 20 shows the area current density versus reverse voltage with temperature as a parameter.

FIG. 21 shows the peripheral current density versus reverse voltage with temperature as a parameter.

FIG. 22 shows the Arrhenius plot for area leakage current versus 1/kT measured at various voltages.

FIG. 23 shows the Arrhenius plot for peripheral leakage current versus 1/kT measured at various voltages.

FIG. 24 shows the mechanism of generation current at (a) low reverse bias and (b) high reverse bias.

FIG. 25 shows the ratio of J_{RP} and J_{RA} versus voltage for various temperatures.

FIG. 26 shows the Arrhenius plot for various areas.

Table 5 shows RTA time, temperature and ramp-down rate condition table for experiment C.

FIG. 27 shows the boron SIMS profile of as-Implanted 40 keV BF₂⁺ with 5×10¹⁵ atoms/cm² dosage and boron profiles after various RTA conditions.

Table 6 shows the junction depth and sheet resistance data for experiment C.

FIG. 28 shows the resistance and calculated doping concentration profile measured by SSM 150 Spread Resistance Probe (SRP).

FIG. 29 shows the cumulative plots of reverse-bias leakage current density with various RTA conditions.

FIG. 30 shows the reverse current-voltage characteristics measured at various temperatures.

FIG. 31 shows the junction leakage current with different diode areas versus P/A ratio.

FIG. 32 shows the Arrhenius plot of area and peripheral current densities.

FIG. 33 shows the area current density versus reverse voltage measured at various temperatures.

FIG. 34 shows the pheripheral current density versus reverse voltage measured at various temperatures.

FIG. 35 shows the Arrhenius plot for area leakage current density measured at various voltages.

FIG. 36 shows the Arrhenius plot for pheipheral leakage current density measured at various voltages.

FIG. 37 shows J_{RP}/J_{RA} ratio versus reverse voltage with different temperatures.

FIG. 38 shows the Arrhenius plot for various diode areas.

FIG. 39 shows a thorough comparison of sheet resistance and junction depth obtained by different techniques.

### DETAILED DESCRIPTION OF THE INVENTION

Formation of Ultra-Shallow Junctions by Diffusion from Implanted Amorphous Silicon

Referring to FIG. 1, a thin oxide is grown first to serve as etching stop layer and a highly doped amorphous silicon layer is formed by ion implantation. In a subsequent RTA step, the dopant diffuses into the underlying silicon to form a p-n junction. Both layers are removed by wet etching after junction formation.

Implantation through the pre-deposited amorphous-Si layer controls the channeling of dopants during implantation, while projection peak defects can be confined within the amorphous layer and thus suppresses the TED effect. Therefore easy-to-control high implantation energies and large dosages can be applied to form highly doped layers. The out diffusion mechanism to form junctions offers the advantage of full-activation of dopants and zero damage induced defects.

Using amorphous silicon as the screening layer before ion implantation is more advantageous than oxide, because of the difference in the diffusivity of dopants in these two films. The diffusion coefficient in amorphous silicon is larger than the diffusion coefficient in oxide (3×10⁻⁴ cm²/s). Therefore, using amorphous silicon would not constraint the amount of dopant diffusing into the junction. Junctions with high surface doping concentration can be formed. Another reason for not using oxide, is that RTA with an oxide-capping layer will induce oxygen enhanced diffusion (OED). Enhancement of boron diffusivity will result in increase of junction depth.

A similar approach to reduce dopant channeling is the use of pre-amorphization implants. However, the additional Ge-implantation itself could introduce end-of-range defects, forming a zone of interstitial dislocation loops near the amorphous-crystalline interface. Complete removal of ion-implantation-induced defects is a serious concern in producing low leakage current junctions. Additional defects will also enhance the TED effect. The merits of a screening amorphous layer before ion implantation is taken and modified here. By pre-deposition of a surface amorphous layer, dopant channeling can be controlled without an additional implantation step.

In this matter, reproducible fully activated junctions are formed while there is virtually no implantation damage in the silicon. Extraordinary results are presented.

Three sets of experiments for DIA, focusing on the junction diffusion mechanism (A), effect of implantation energy (B), and effect of RTA temperature and time (C) are proposed.

DIA Experimental Procedure

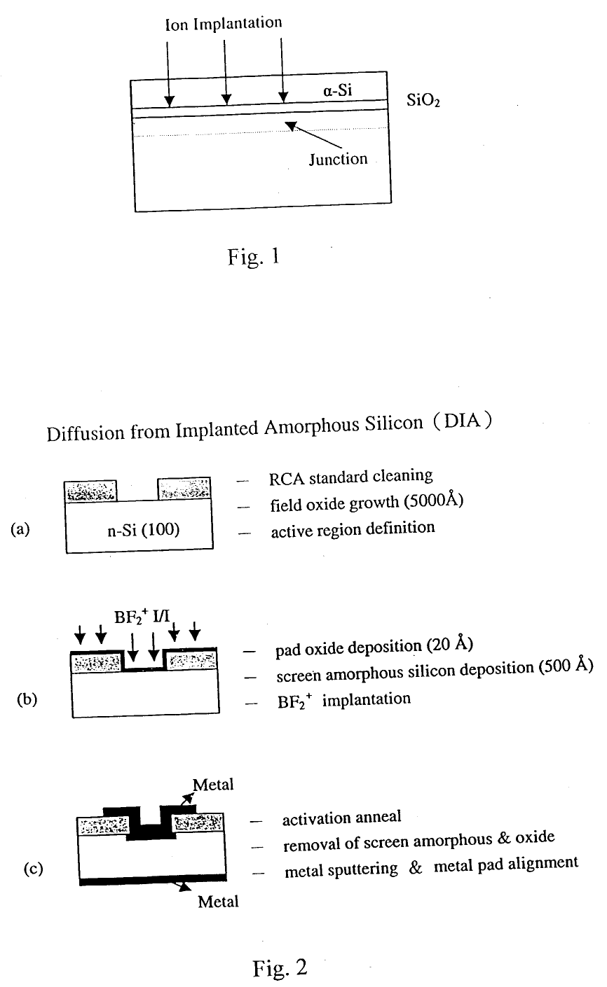

Materials used for the formation of ultra-shallow junctions were n-type, phosphorus-doped, (100) oriented silicon wafers with a nominal resistivity of 4-7 Ω-cm. After standard RCA cleaning, a 5000 Å thick SiO₂ was thermally grown at 1050° C. in a pyrogenic atmosphere. Active regions were defined using the conventional photolithographic method and wet etching technique. A padding oxide with thickness of 20 Å was grown by N₂O HDPCVD (high density plasma chemical vapor deposition) as the etch-stop layer for later etching of amorphous silicon. The screening amorphous silicon layer of 500 Å was deposited by LPCVD (low pressure chemical vapor deposition). Various energies and doses of BF₂⁺ were implanted into the screening amorphous-Si layer, followed by various RTA processes. Afterwards, the amorphous-Si layer was removed by conventional poly-Si etching solution (HNO₃+H₂O+NH₄F), and the thin etch-stop oxide was removed by BOE (HF:NH₄F=6:1). Wafers were loaded into a PVD (physical vapor deposition) system immediately following the screen oxide removal, and a 5000 Å thick Al—Si—Cu film with a TaN buffer layer was deposited. Metal pad alignment was defined and Al—Si—Cu was deposited on the backside of the wafer. FIG. 2 illustrates the process flow of DIA sample preparation.

1. Experiment A: DIA Junction Formation Mechanism

In experiment A, BF₂⁺ dopant is used with implant energy of 40 keV and dosage of 5×10¹⁵ atoms/cm². The RTA condition table is shown in Table 1. RTA conditions are 950° C. 5 s, 1050° C. 5 s and 1050° C. 1 s.

1.1. Junction Depth and Sheet Resistance

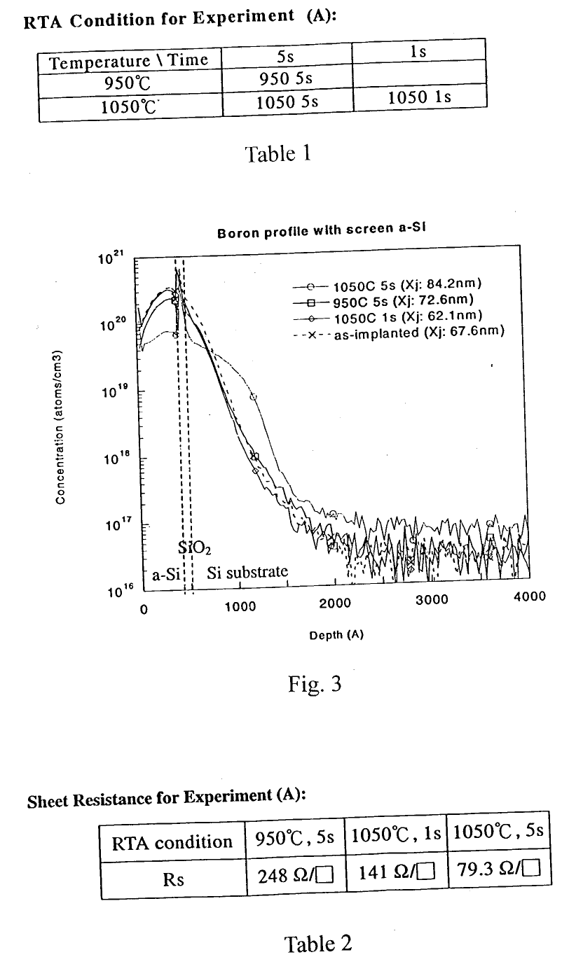

The boron Secondary Ion Mass Spectroscopy (SIMS) profiles for the samples with and without RTA are shown in FIG. 3. The screen amorphous layer was reserved to observe the boron distribution through screen amorphous silicon, pad oxide and the silicon substrate. The as-implanted projection peak is controlled inside the amorphous silicon to confine the defects inside the screen layer. The boron profile exhibits two discontinuous points at the oxide boundaries (depth about 45 nm and 52 nm), Due to mass disturbance effect in SIMS measurement, quantitative analysis is not available in the oxide region; precise oxide interface cannot be determined exactly also. However, we can see that the thin oxide layer does not affect the Gaussian implant profile. A padding oxide layer will not influence the implant or diffusion of dopants if the oxide thickness is limited. The as-implanted junction depth is 67.7 nm, and the junction depth after RTA are 72.6 nm, 84.2 nm, and 62.1 nm respectively for RTA conditions 950° C. 5 s, 1050° C. 5 s and 1050° C. Is. The boron concentration at the junction surface is as high as 2×10²⁰ atoms/cm³, close to the solid solubility limit. Comparing the boron distribution of RTA samples with the as-implanted profile, we can see that steep junctions with slopes similar to the as-implanted profile can be formed. We presume that DIA junction formation reduces the amounts of implantation defects and thus the TED effect.

It can be seen that dopant channeling still causes a boron distribution tail. This can be explained by comparison with the research of implant through thin screen oxides. Implantation through screen oxide focuses on reducing the channeling effect; however, it has been found that boron atoms will encounter scatter-in channeling effects. As boron atoms travel through oxide, nuclear scattering by the amorphous layer spreads the angular distribution of the ion beam. Using a tilted implant, the ion beam is initially directed off the <100> axial channels. But as a result of scattering in the oxide layer, a fraction of ions may be directed back into the <100> axial channel. However, the scatter-in channeling effect is small compared to direct channeling. Channeling effect is reduced dramatically by DIA.

Table 2 presents the sheet resistance of these samples. Sheet resistance are 140^{˜}240 Ω/□, close to the ideal sheet resistance value for junctions of 60^{˜}80 nm. Therefore, high amounts of dopants can be incorporated and are fully activated.

1.2. Diffusion Mechanism

The diffusion mechanism for DIA junctions can also be observed from the SIMS profile in FIG. 3. We can see that at short RTA time (1050° C. 1 s) the B profile peak shifts left instead of diffusing inward. This dopant out-diffusion is commonly observed during junction RTA. The screening amorphous silicon therefore acts as a capping layer to suppress the amount of out-diffused dopants. At low temperatures with longer RTA time (950° C. 5 s sample), out-diffusion at the projection peak is also observed. However, focusing on the boron tail profile after 1000 Å, the 950° C. 5 s sample exhibits inward diffusion. The 1050° C. is sample does not. Therefore, sufficient RTA time is required to overcome out-diffusion, the screen amorphous layer then acts as a diffusion source and the dopant profile diffuses inward. A deep junction is formed from the inward diffusion of dopants at the annealing condition of 1050° C. 5 s. The boron distribution in the amorphous layer decreases after long RTA times from inward and out-diffusion.

1.3. Summary of Experiment A

We can conclude that the diffusion mechanism during RTA is first outward diffusion, while dopants diffuse from the screen amorphous layer after longer RTA duration. The screening amorphous silicon first acts as a capping layer to suppress the amount of out-diffused dopants. After longer RTA time, the amorphous layer then acts as a diffusion source and the dopant profile diffuses inward. This is consistent with the concept of DIA junction formation method.

2. Experiment B: Dependence of DIA Junction on Implantation Energy

In experiment B, the BF₂⁺ implantation energy is 35 keV, 40 keV, 45 keV, 50 keV with dosage of 2×10¹⁵ atoms/cm². The RTA condition table is shown in Table 3. RTA temperatures vary from 900° C. to 1000° C. with different annealing time.

2.1. Junction Depth and Sheet Resistance

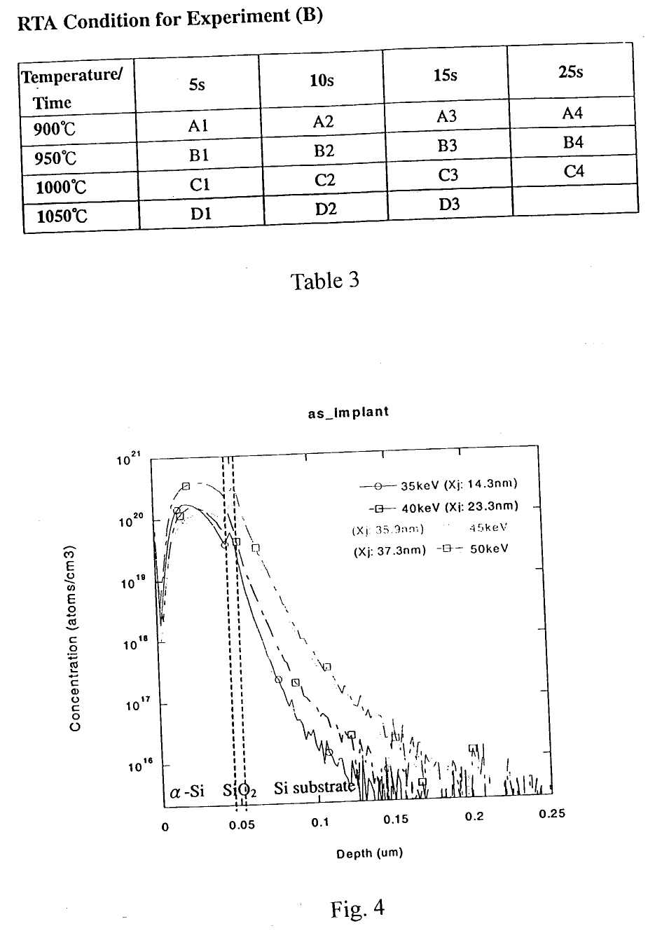

The as-implanted boron SIMS profile, as in FIG. 4, exhibits the boron distribution through screen amorphous silicon, pad oxide and the silicon substrate before RTA. The implantation projection peaks are controlled to be inside the amorphous silicon to confine the defects inside the screen layer. As predicted, higher implantation energy implants the dopants deeper into the wafer. The boron profile shows two discontinuous points at the oxide boundaries (depth=45 nm and 57 nm). The as-implanted junction depths are 14.3 nm, 23.3 nm, 35.9 nm, and 37.3 nm respectively for implantation energies of 35 keV to 50 keV. Peak boron concentrations at the Si substrate surface, or junction surface, are about 1×10¹⁹ atoms/cm³ for 35 and 40 keV implants, and about 1×10²⁰ atoms/cm³ for 45 and 50 keV implants. This states that low dopant implant energies places the concentration peak too far away from the junction interface, resulting in a low initial interface concentration. Our results show that though higher implantation energy results in deeper junction depths, its large peak concentration is advantageous to form low sheet resistance. The considerable difference in junction surface concentrations will greatly affect device characteristics.

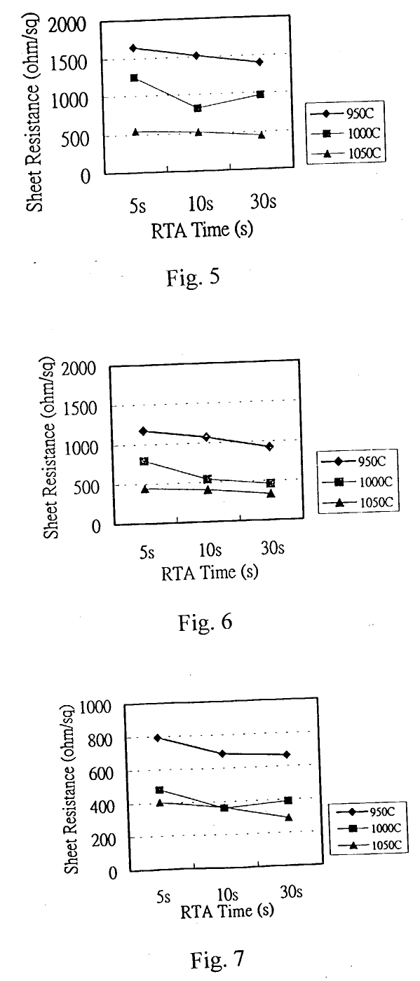

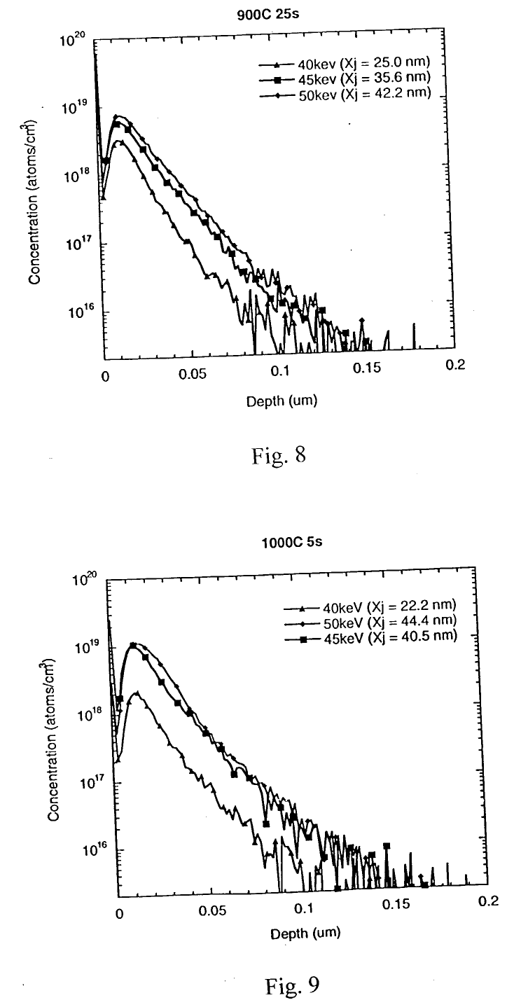

FIG. 5, 6, 7 shows the relation between junction sheet resistance and junction depth with RTA temperature after dopant activation for the BF₂⁺ 40 keV, 45 keV and 50 keV samples respectively. The DIA junction exhibits low sheet resistances, even <800 Ω/□ for the 50 keV sample (FIG. 7). The junction resistance decreases with the increase of RTA temperature and time. By comparison of these three figures, we can see that the junction resistance also decreases with the increase in energy of implant. The actual junction depth is determined by SIMS measurement, which is shown in FIG. 8, 9, 10. Generally, the junction depth should increase with the implant energy, RTA temperature and RTA time.

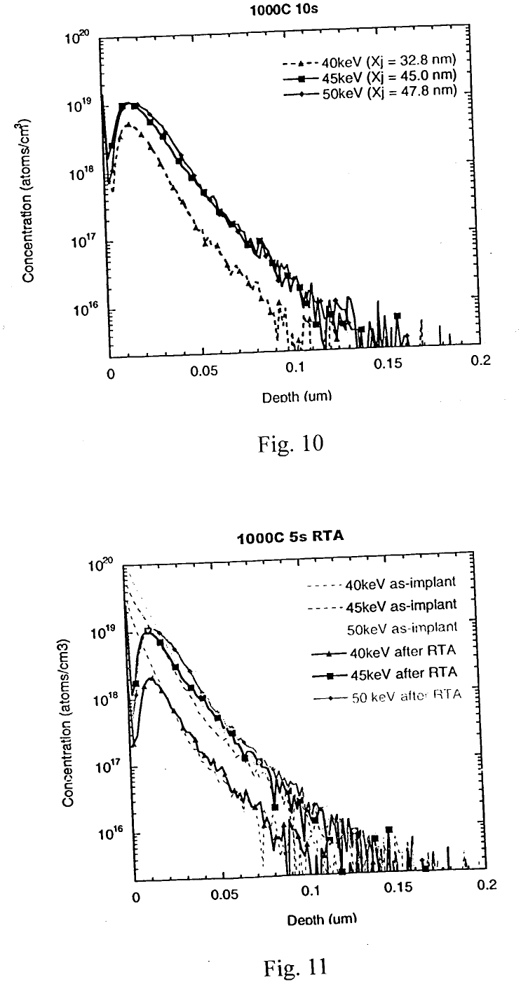

In FIG. 8, 9, 10 the SIMS data for RTA conditions of 900° C. 25 s, 1000° C. 5 s, and 1000° C. 10 s are shown. Surface and Interface analysis of SIMS measurement exhibit near surface effects. Samples with surface native oxide will cause spike surface signals and require a front stabilization region. Removal of the surface effect requires normalization by pumping oxygen to grow a surface oxide during measurement. The surface-effect of SIMS profiles was not removed here because of the lack of oxygen source. The junction depth defined at B concentration of 10¹⁸ atoms/cm³, is shown with the curve label. The depth of the p-n junction increases with implant energy. Junction depth also becomes deeper with increasing RTA time, as shown in FIG. 9, 10. And higher RTA temperatures also enhance dopant diffusion (FIG. 8, 9).

However, after comparing the boron profiles of samples with equal implant energy but varying RTA conditions, we noticed that the effect of different RTA conditions is not obvious. Various RTA conditions only cause a 5-10 nm difference in junction depth, while the junction depth is mainly decided by the initial implantation energy. That is, compared to the effect of RTA, the junction depth has an even stronger dependency on the implantation energy.

The boron SIMS profiles of the 1000° C. 5 s RTA sample are shown with the as-implanted profiles to observe the diffusion of dopants after RTA in FIG. 11. The SIMS surface-effect of RTA samples was not removed. The junction depth increases only 5^{˜}10 nm after RTA. Similar results are acknowledged in the samples with 950° C. 25 s and 1000° C. 10 s. Surface boron concentrations fall about one order resulting in a surface concentration of 1019 atoms/cm³ for the 40 keV sample, a smaller drop is observed for 45 and 50 keV samples for ˜10²⁰ atoms/cm³. The insufficient dopant concentration for the 40 keV sample resulted in large sheet resistance. However, the 45 and 50 keV samples with large peak concentration are advantages to form low sheet resistance junctions. It is also worth noticing that the B profile slopes before and after RTA are similar, meaning that steep junctions can be made with the DIA method.

Table 4 show a summary of the junction depths of these various RTA and implant conditions.

2.2. p⁺ n Junction Leakage Current

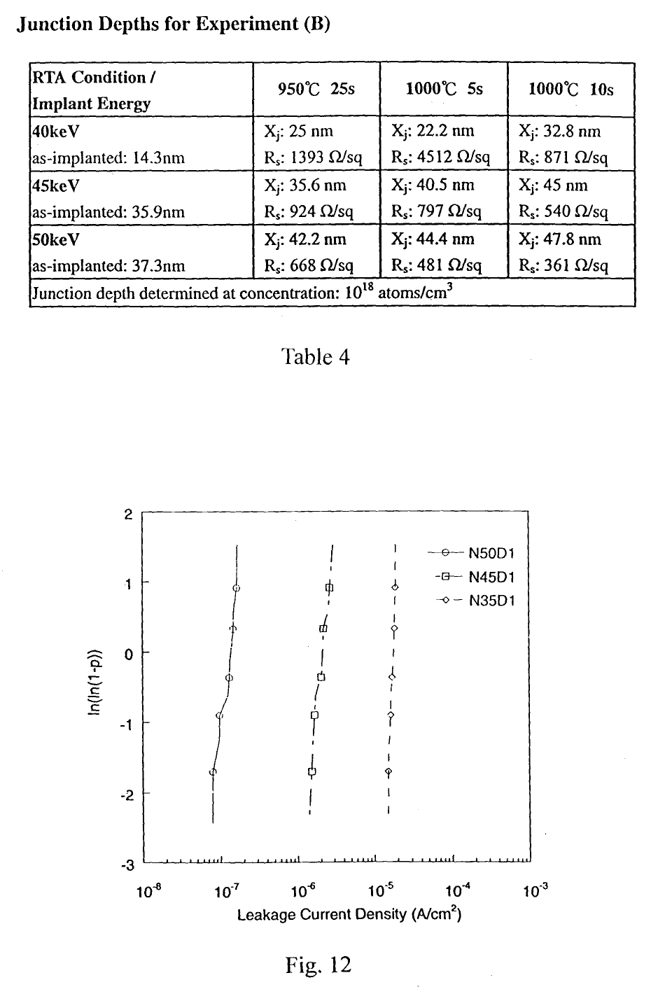

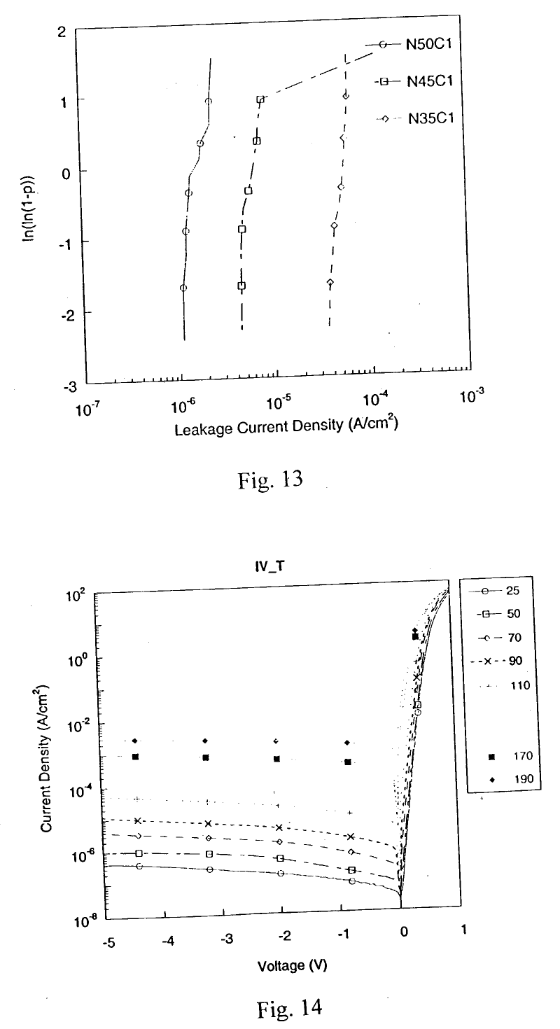

FIG. 12 and FIG. 13 show the cumulative plots of reverse bias leakage current density for the DIA junctions with various implant energies. The diode area measured is 100×100 μm. Junction leakage current decreases with implant energy regardless of the RTA condition. This should be due to the deeper junctions of high-energy samples. Deeper junctions exhibit lower leakage currents. This is because junction defects are usually located near the wafer surface. Shallow junctions therefore consist mostly of these defected regions. However, leakage current paths are blocked as junctions deepen into the single crystal substrate. Therefore, the leakage current decreases with the increase of junction depth. We might conjecture that the 40 keV leakage current density should be somewhere in between the 45 and 35 keV plots. The low leakage current density of the 45 keV and 50 keV samples, about 10⁻⁷ A/cm²; are suitable for device applications.

2.3. Reverse Bias Junction Leakage Characteristics

In this section, we will discuss the reverse junction characteristics. The current-voltage characteristics of the junctions formed by DIA were measured with square diodes using HP4156 semiconductor parameter analyzer. The reverse current-voltage characteristics (I_{R} versus V_{R}) measured at various temperatures are given in FIG. 14.

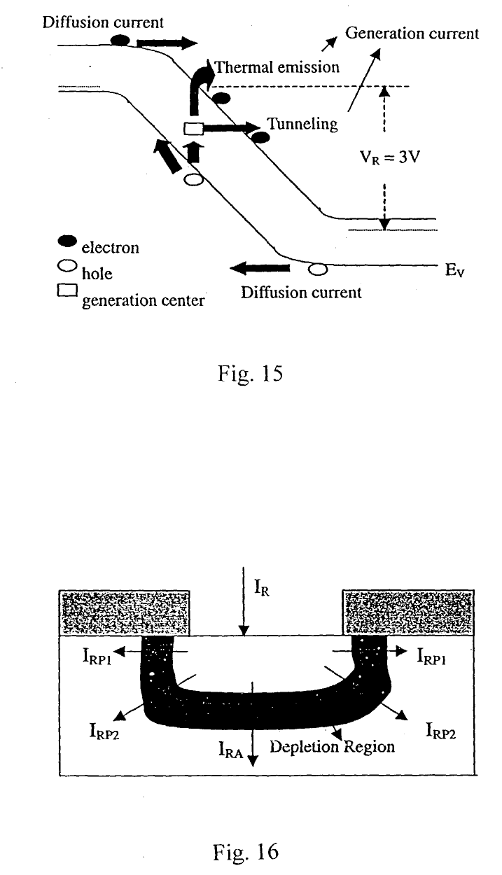

FIG. 15 shows the schematic of junction leakage components in a reverse-biased junction. The total reverse current of a diode can be approximately given by the sum of the diffusion components in the neutral region and the generation current in the depletion region as shown in equation 1:

J_{R}=J_{diff}+J_{gen}=qADnᵢ²/(N_{A}×L_{d})+qAnᵢW/2τ (eq. 1)

where A is junction area, D is diffusion coefficient, nᵢ is intrinsic density, N_{A} is acceptor impurity density, L_{d} is diffusion length, W is the depletion width, and τ is effective lifetime.

In equation 1, I_{diff} is proportional to T³exp(−E_{A}/kT) and I_{gen} is proportional to T^{3/2}exp(−E_{A}/2 kT), where E_{A} is the activation energy. For diffusion current, E_{A} equals E_{g} (energy gap of Si), while E_{A} equals E_{g}/2 for generation current. The two junction leakage components, junction area leakage current density (J_{RA}) and junction periphery leakage current density (J_{RP}), as shown in FIG. 16 can be separated:

I_{R}=A×J_{RA}+P×J_{RP}+ΔI

J_{R}=J_{RA}+(P/A)×J_{RP}+ΔI/A

J_{RP}=J_{RP1}+J_{RP2}

J_{RP1}: peripheral current density along silicon/oxide interface (A/cm)

J_{RP2}: peripheral current density along peripheral edge (A/cm)

where A: junction area (cm²)

P: junction periphery (cm)

J_{RA}: area current density (A/cm²)

J_{RP}: peripheral current density (A/cm)

ΔI: system leakage current

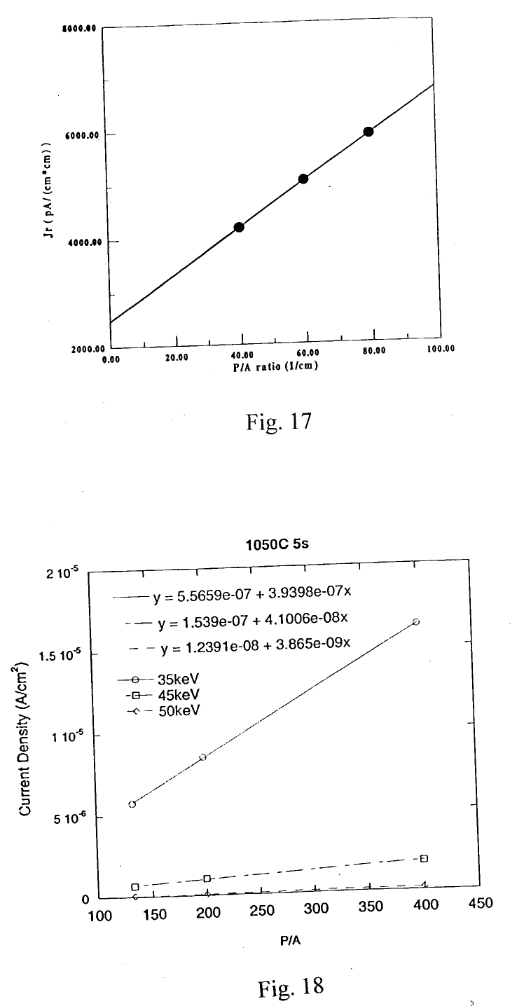

If the reverse leakage current density is plotted as a function of P/A ratio, the slope is J_{RP} and the intercept with Y-axis is J_{RA}, as shown in FIG. 17. In this study, we find that this method applies to DIA junction most successfully.

Diodes with area of 100×100 μm, 200×200, m and 300×300 μm are measured. The reverse junction current at −3V is determined to be their leakage current for the peripheral versus area ratio plot. FIG. 18 is the P/A ratio for the 1000° C. 5 s RTA sample with various implant energies. Implantation defects are usually largest at the projection peak, which is usually near the junction surface. Therefore, defects leading to junction leakage are mostly near the junction perimeter. While the Si and oxide interface also induces interfacial traps. Thus the periphery is the dominant leakage path; the effect of the perimeter can be shown in P/A ratio plot. As the slope of the P/A ratio plot decreases with increasing implant energy, we can assume that the effect of defects on the junction is smallest for the 50 keV sample. We presume that this is because of the deeper junction formed by high-energy implants. Because the implantation defect influences the junction peripheral leakage, in deeper junctions the proportion of defect-containing peripheral is smaller. We hope to observe a more significant reduction in implantation defects by the DIA method in the 50 keV samples. The activation energy is measured for further verification of this effect.

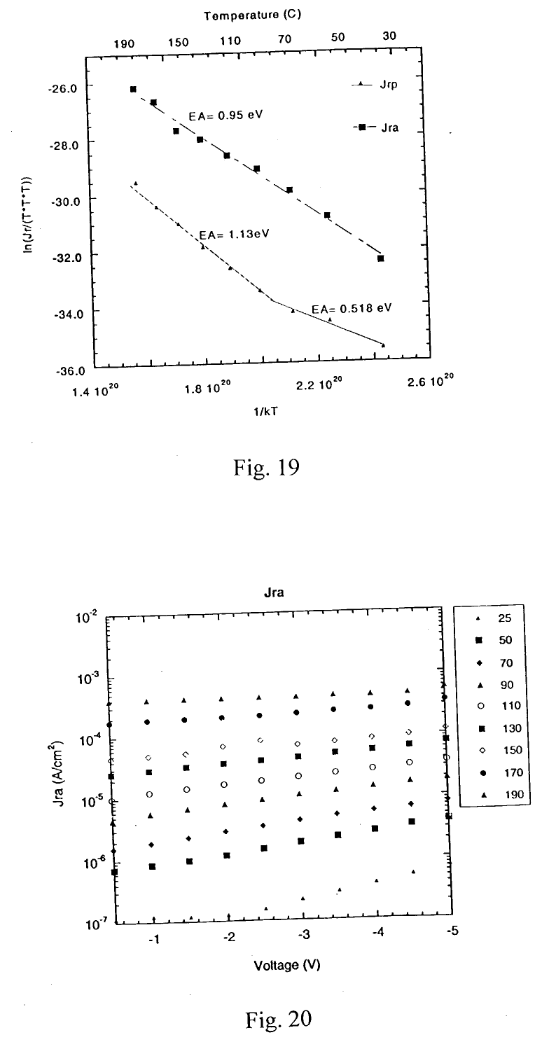

J_{RA} and J_{RP} are both the sums of diffusion current and generation current. So we can gain insights into junction characteristics by analyzing J_{RA} and J_{RP}. In order to investigate the area and peripheral current mechanism, the dependence of the reverse current (i.e., ln(J_{RA}/T³) and ln(J_{RP}/T³) versus 1/kT) was examined as shown in FIG. 19. Reverse junction was measured at varying temperatures from 25° C. to 190° C., the leakage current for p n junction diodes was determined at −3V. The Arrhenius plot slope (In Jr/T³ versus 1/kT) is the activation energy. Activation energy for area leakage current density is 0.95 eV close to the E_{g}(1.12 eV) of Si. This indicates that no significant defect is produced by the implantation step in area region, and diffusion current dominates J_{RA}. For peripheral current density, there are two different slopes. At low temperature, E_{A} is 0.52 eV ^{˜}E_{g}/2. J_{RP1} dominates J_{RP} at this region, because there are some interface states along the silicon/oxide interface. Defects in the junction act as generation centers, which reduce the activation energy. As a result, the generation current dominates in this temperature regime. At high temperature, EA is 1.13 e V. The higher activation energy denotes that J_{RP2} is the dominant current of J_{RP} at this region. Diffusion current is the major leakage component. The slopes for J_{RP} and J_{RA} are 0.95 eV and 1.13 eV respectively at the high temperature region. The reason is that, for peripheral current density, there are some traps at the silicon/oxide interface. No substantial defects are produced by the implantation step.

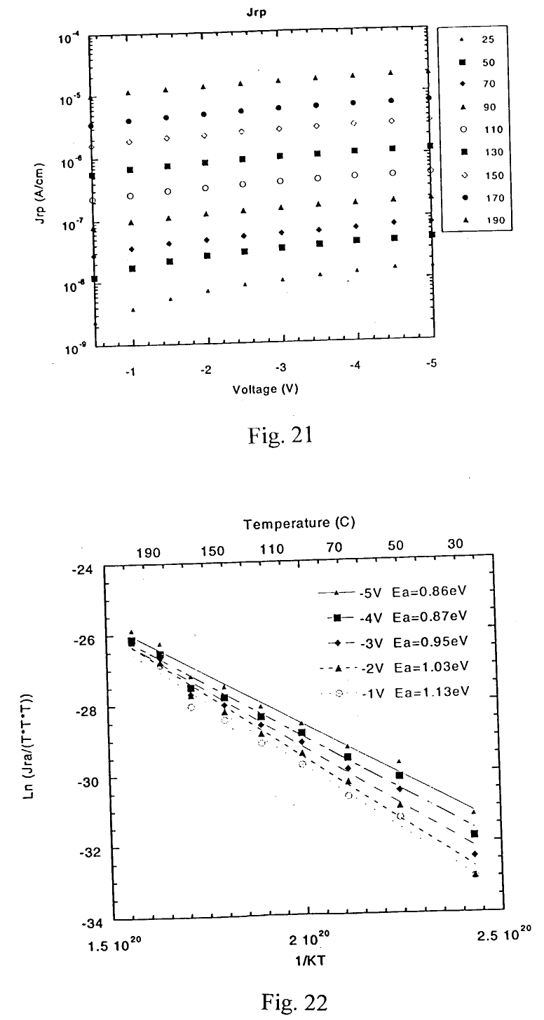

FIG. 20 shows the area current density versus reverse voltage with temperature as a parameter. For an ideal junction J_{RA} should be voltage independent. This is because no defect is produced in area region and the diffusion current dominates J_{RA}, so the area current is independent of voltage. However, due to the junction series resistance, a linear relationship between leakage current and voltage is observed. FIG. 21 shows the peripheral current density versus reverse voltage with temperature as a parameter. We can see that J_{RP} is more dependent on the bias voltage.

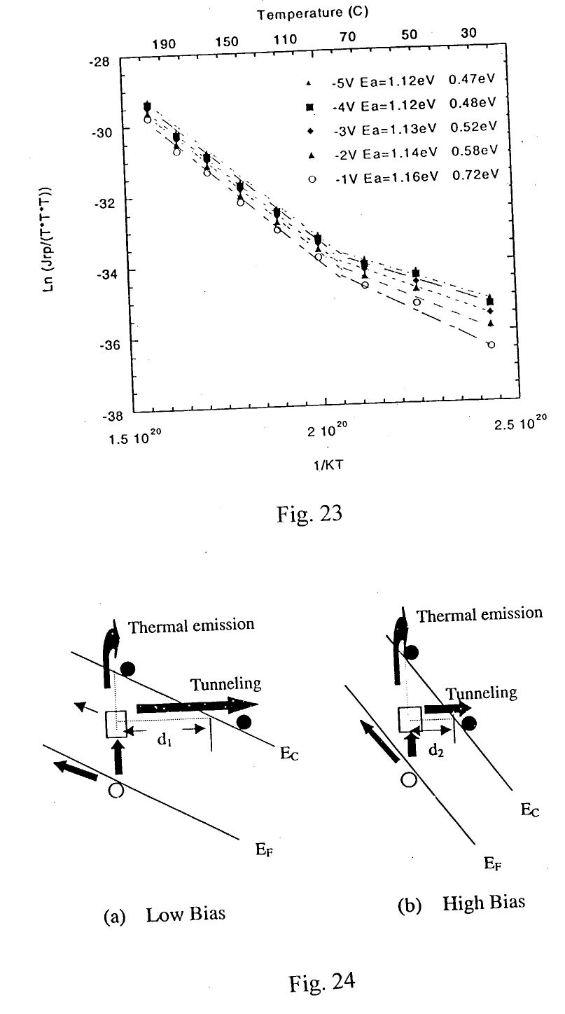

The Arrhenius plots for area and periphery leakage current measured at various voltages is shown in FIG. 22 and FIG. 23. The calculated activation energy for the area leakage is about 1 eV. The Arrhenius plot for periphery leakage current exhibits activation energy of 1.1 eV at high temperatures where diffusion current dominates. Activation energy for low temperatures, however, decreases with increasing reverse voltage. At low bias, thermal emission is the major mechanism for generation current. But, at high bias, tunneling distance obviously is shorten (d₁>d₂), as shown in FIG. 24. Generation current increases greatly because of higher tunneling possibility. Therefore, the activation energy is reduced. The temperature, at which the dominant mechanism turns from generation into diffusion, is about 90° C.

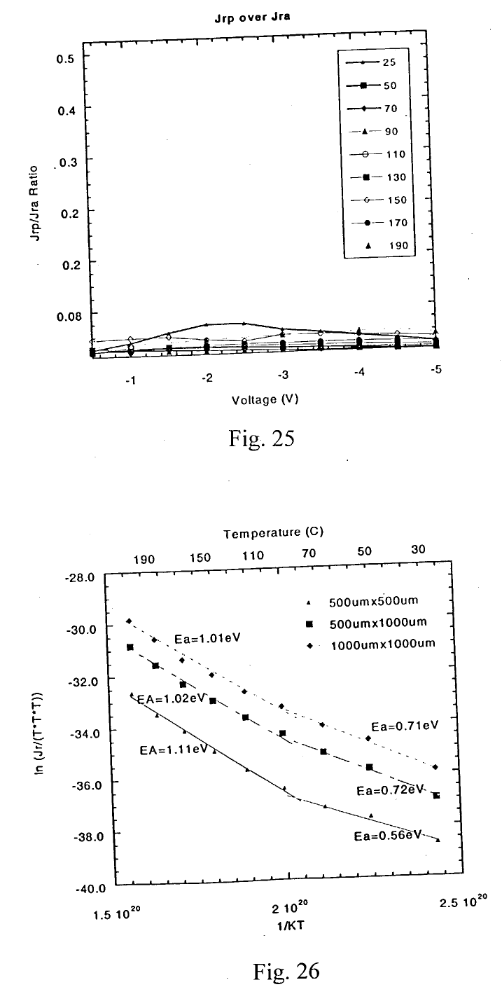

The ratio of J_{RP} and J_{RA} versus voltage for various temperatures is shown in FIG. 25. Though J_{RP} and J_{RA} increase with applied voltage, the J_{RP}/J_{RA} ratio remains nearly the same. Therefore, no significant junction leakage is observed in the DIA junction formation method. FIG. 26 shows In (I_{R}/T³) versus 1/kT with various areas of 500×500 μm, 1000×500 μm and 1000×1000 μm. The activation energy remains almost the same ^{˜}1 eV. The temperatures, at which the dominant mechanism turns from generation into diffusion, are about 90^{˜}100° C. This result is consistent with previous observations.

2.4. Summary of Experiment B

DIA can form shallow and steep junctions with high surface concentrations, low resistance and good electrical properties. Implanting through amorphous silicon reduces dopant channeling and confines the implantation peak defects within the screen layer. Nearly no defects are observed in the junction area region from the Arrhenius plot. However, probable defects are formed at the junction peripheral region. To determine whether these defects are implantation related, the implantation energy was reduced to 40 keV for subsequent experiments.

3. Experiment C: Dependence of DIA Junction on RTA condition

In experiment C, the BF₂⁺ implantation energy has been lowered to 40 keV with dosage of 5×10⁵ atoms/cm². The RTA condition table is shown in Table 5. RTA time, temperatures and ramp-down rates (presented in the form of nitrogen purge flow rate) are variables influencing junction formation. The concept of faster ramp-down rates on junction depth and dopant activation concentration is also explored in this section.

3.1. Junction Depth and Sheet Resistance

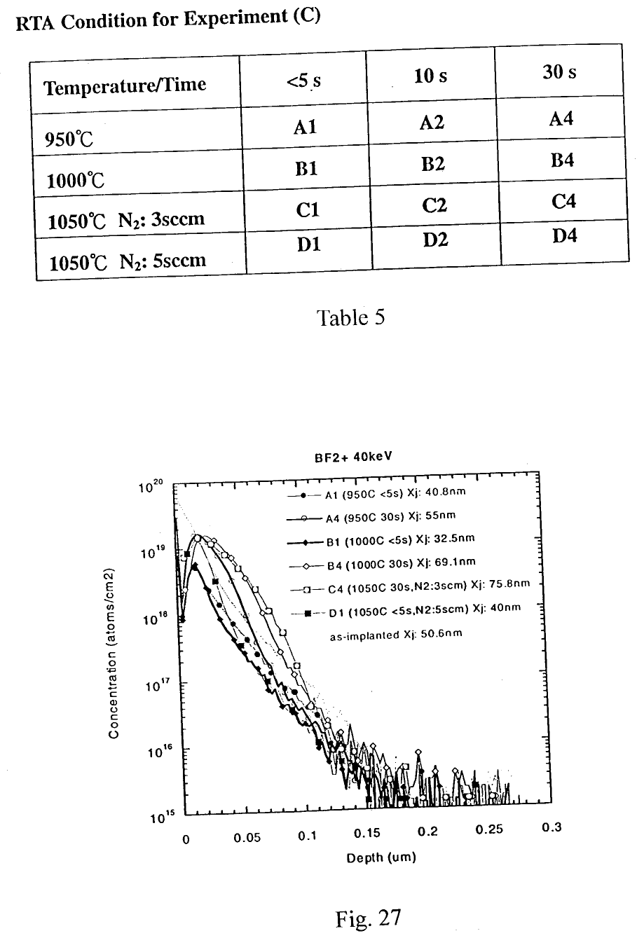

FIG. 27 shows the as-implant and post-RTA boron SIMS profiles in a p-n junction. SIMS surface effect was not removed for the RTA samples. The as-implanted junction depth is 50.5 nm. Out-diffusion mechanism at short RTA time is also observed in Experiment C for the 950° C., 1000° C. and 1050° C.<5 s samples. Long RTA times and higher RTA temperatures diffuse the dopant deeper into the substrate. Junction depths of these samples determined at 10¹⁸ atoms/cm³ are shown in the plot insert label. Peak dopant concentrations are in the order of 10^{19˜}10²⁰ atoms/cm³.

The effect of ramp-down rate on junction depth has been evident. A faster ramp-down rate is effective in suppressing boron diffusion and obtaining high activation. Shallow and steep junctions with high concentration thus can be formed. In rapid thermal processing instruments, wafers are instantly heated by lamps surrounding the chamber. However, cooling of the wafer depends on a nitrogen flow through the chamber. Ramp-down rate resembles the cooling rate, which is the rate of the nitrogen purge flow. Typical N₂ flow rate used is 3 sccm; to increase the ramp-down rate, the N₂ flow was increased to 5 sccm. The D1 sample (1050° C., <5 s, N₂: 5 sccm) exhibits results corresponding to that reported by others. A steep junction of 40 nm depth with peak concentration comparable to the as-implanted profile is obtained.

Junction depth and sheet resistance of Experiment C are collected in Table 6. Sheet resistance decreases with the increase in junction depth. Though the junction depth of C1 sample (1050° C., <5 s, N₂: 3 sccm) measured by SIMS is not available, it can be speculated to be around 50 nm from the sheet resistance values. The influence of ramp-down rate on junction depth thus can be certified. More evidence of this effect is also shown from electrical results in a later section.

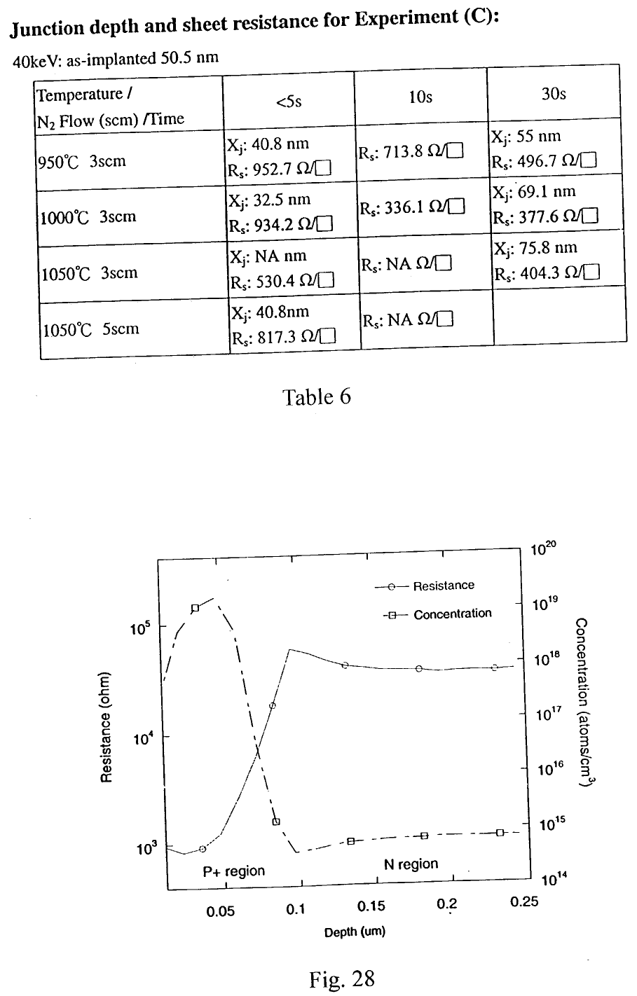

FIG. 28 is the resistance and calculated doping concentration profile measured by SSM 150 Spread Resistance Probe (SRP). Spreading resistance measurement provides an electrical measurement of the active concentration. When converting the raw spreading resistance into dopant concentration, only dopants that are electrically active, meaning they are on lattice sites, can be measured. By comparing the boron profile of SIMS and SRP analysis, the ability of annealing on dopant activation can be examined. For sample D1 (1050° C., <5 s, N₂: 3 sccm), the peak dopant chemical concentration (SIMS) is around 4×10¹⁹ atoms/cm³. From FIG. 28 the peak electrical concentration (SRP) is also about 4×10¹⁹ atoms/cm³. Full activation of dopants is available in association with DIA junction formation using Dl RTA condition.

3.2. p⁺ n Junction Leakage Current

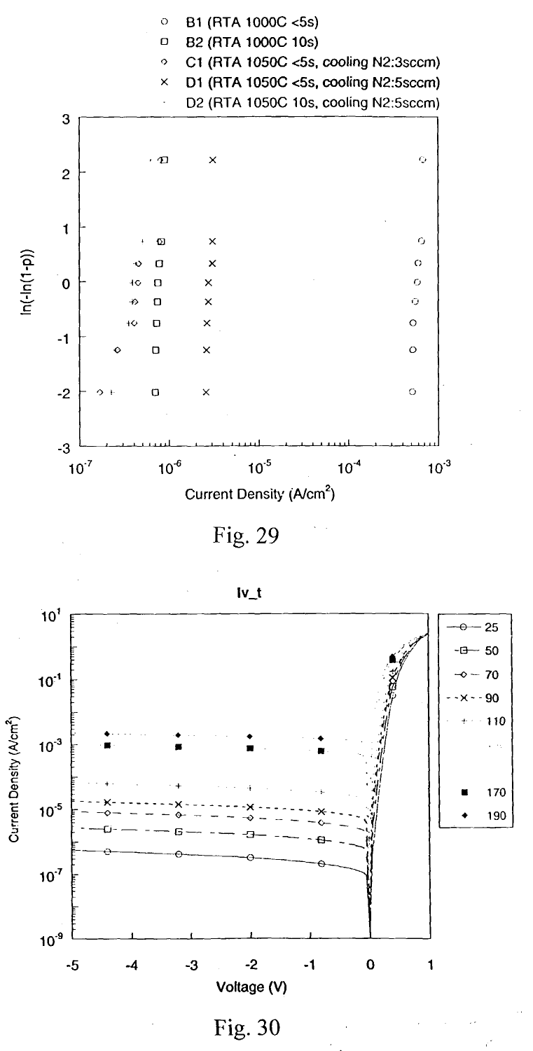

Cumulative plots of reverse-bias leakage current density with various RTA conditions are shown in FIG. 29. Leakage current density of three RTA temperatures, 950° C., 1000° C. and 1050° C. were found to decrease with the increase in temperature. Longer RTA times have shown to suppress leakage current also. This is consistent with the results in previous sections. Deeper junctions exhibit smaller leakage currents. A major concern for large RTA ramp-down rates is the uniformity of wafer cooling. From the cumulative leakage plots, we can see that wafer uniformity is good, even for the D1 RTA condition.

Leakage current of C1 (1050° C., <5 s, N₂: 3 sccm) is the smallest of the samples in FIG. 29. Assuming leakage current is dependent of junction depth, we can presume that C1 has a deeper junction than D1. This provides further verification of the effect of RTA ramp-rates on junction depth.

3.3. Reverse Bias Junction Leakage Characteristics

The current-voltage characteristics of the junctions formed by DIA were measured using HP4156 semiconductor parameter analyzer. The reverse current-voltage characteristics (I_{R} versus V_{R}) measured at various temperatures are given in FIG. 30.

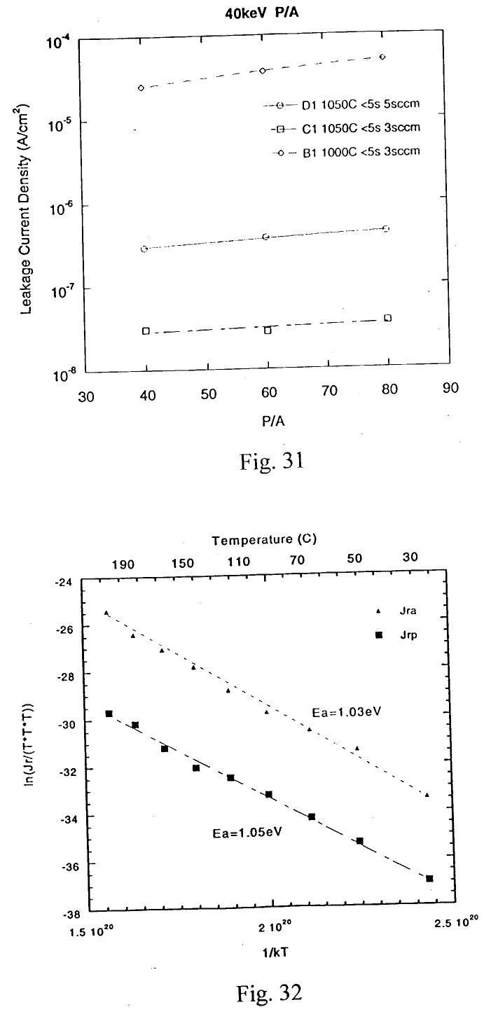

In FIG. 31, Junction leakage current from three diodes with different areas 500×500 μm, 1000×500 μm, and 1000×1000 μm were measured and plotted as a function of P/A ratio. P/A ratio is shown to be independent of RTA condition. This suggests that defects in the junction have been reduced and its effect on junction P/A is minor. Junction area and peripheral leakage will be discussed separately.

To gain insights into junction characteristics by analyzing J_{RA} and J_{RP}, the Arrehnius plot for the D1 (1050° C., <5 s, N₂: 5 sccm) sample has been shown in FIG. 32. Both J_{RA} and J_{RP} exhibit activation energies close to the E_{g} of Si, 1.03 eV for J_{RA} and 1.05 eV for J_{RP}. Therefore, nearly no defects are produced in both the junction area and peripheral regions from implantation, and diffusion current dominates in these regions. The temperature, at which the dominant mechanism turns from generation into diffusion, is now suppressed to below room temperature. We conjecture that removal of all defects is the result of lower implantation energy used. As we reduced the implant energy from 50 keV to 40 keV, the implantation peak is certified to be entirely inside the screen amorphous layer. Thorough removal of implantation defects is accomplished.

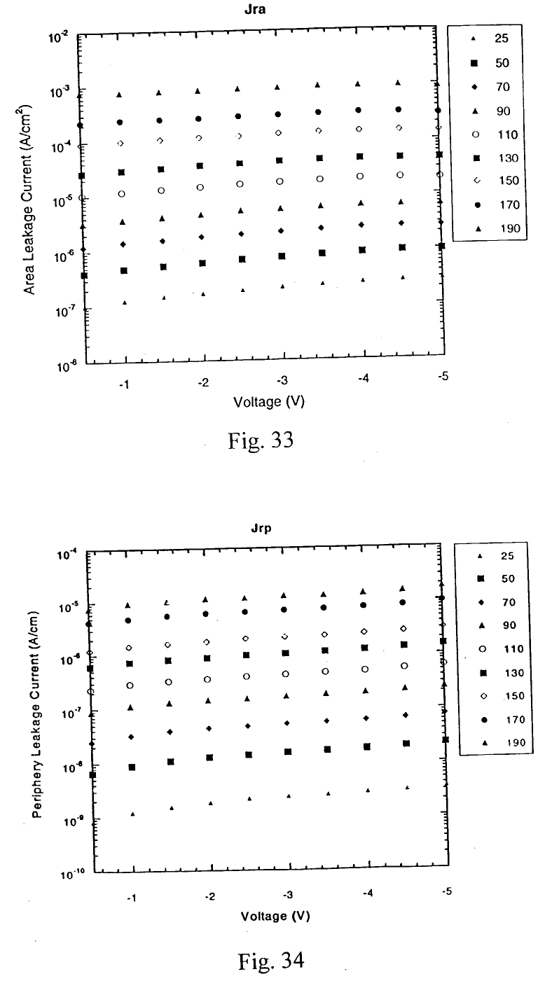

FIG. 33 and FIG. 34 are the area and peripheral current density versus reverse voltage measured at various temperatures. Both J_{RA} and J_{RP} are independent of reverse voltage. This also confirms the fact that nearly no defects are formed in the junction, and diffusion current is the dominant leakage mechanism.

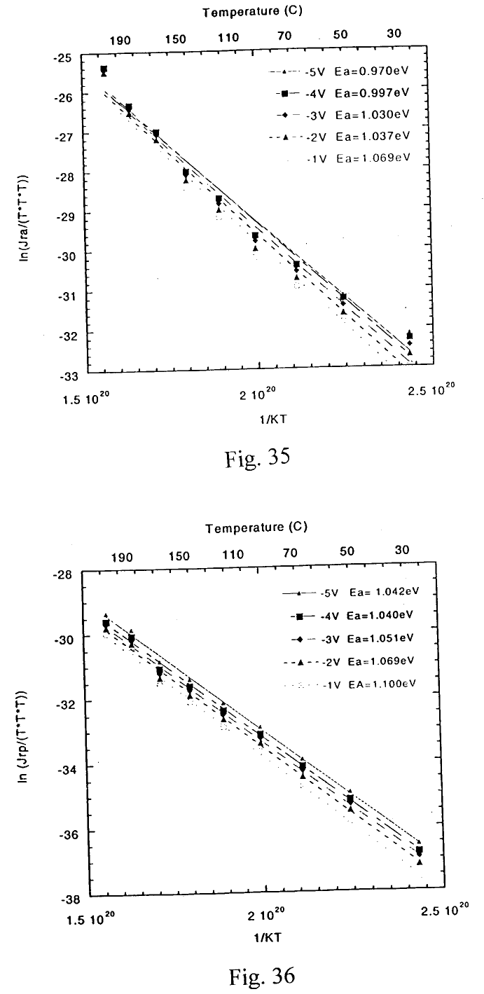

The Arrhenius plots for area and periphery leakage currents measured at various voltages are shown in FIG. 35 and FIG. 36. The calculated activation energy for the area leakage is about 1 eV. The Arrhenius plots for periphery leakage current exhibits activation energy of about 1.05 eV.

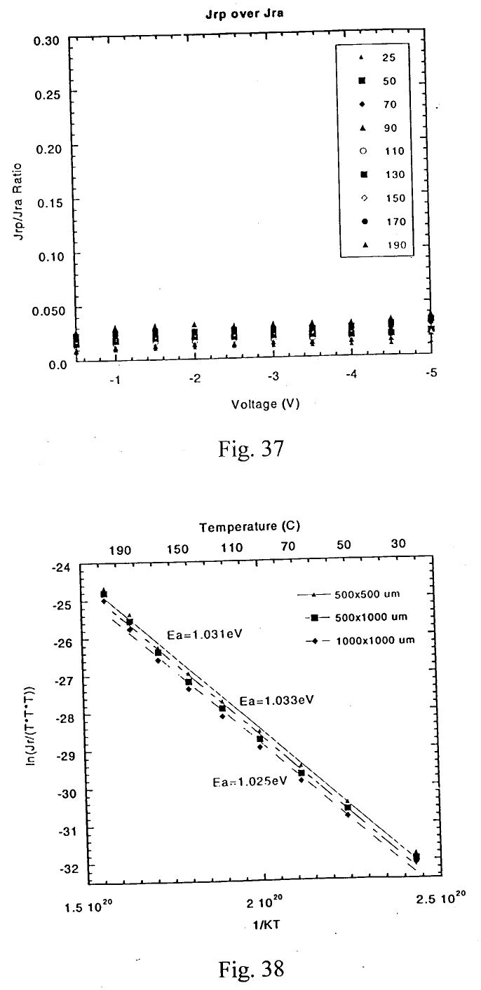

J_{RP} to J_{RA} ratio for various temperatures are shown in FIG. 37. Little variation or dependence on temperature or reverse voltage is observed. Therefore, no significant junction leakage is observed in the DIA junction formation method.

FIG. 38 shows in (IR/T³) versus 1/kT with various areas of 500×500 μm, 1000×500 gi m and 1000×1000 μm. Because both junction area and periphery leakage current are diffusion dominate, activation energy calculated for various P/A ratios are about equal.

3.4. Summary of Experiment C

Junction depth, sheet resistance and electrical properties in DIA junctions are found to be dependent of RTA condition. Junction depth increases with increasing annealing temperature, and RTA time. The RTA ramp-down rate is also explored. Increasing the ramp-down rate has been examined to reduce boron diffusion and exhibit high activation concentrations. By reducing implant energy, the proposed DIA method can form junctions with nearly no implantation defects. Both the area and periphery regions have been explored. The screen amorphous layer is found to be capable of isolating the implantation peak defects.

4. Summary

Shallow and steep junctions with high physical and electrical concentration, and good electrical properties can be formed by the proposed DIA junction formation method. Experimental results are consistent with the concept of DIA method. The screen amorphous layer has removed nearly all implantation defects. A defect-free junction can be formed by DIA.

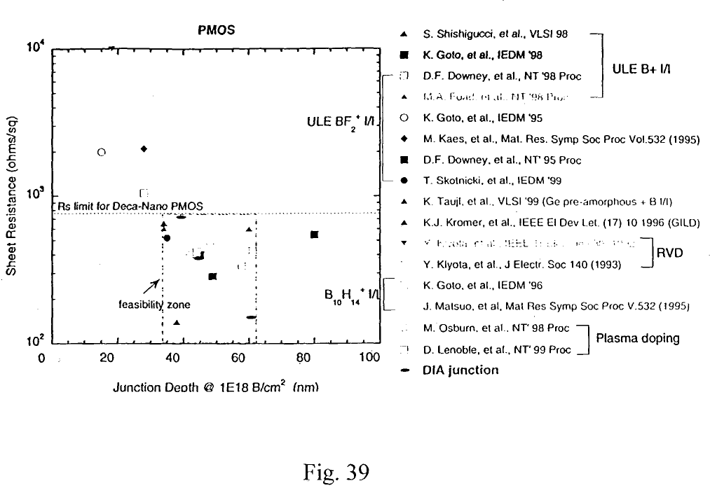

A figure extracted from Skotnicki, shows a thorough comparison of series resistance and junction depth obtained by different techniques (FIG. 39). Our defect-free DIA junction is marked additionally on this figure. We can see that the DIA junction lands in the feasibility zone for deca-nano PMOS applications.

The spirit and scope of the present invention depend only upon the following claims, and are not limited by the above embodiments.

What is claimed is:

1. A process of ultra-shallow junction formation for nano mos devices using amorphous-si capping layer, comprising steps of:
a. in a standard CMOSFET manufacturing process, an active area is defined in a silicon substrate, and then a gate dielectric layer and a gate electrode are formed in said active area;
b. forming a SiO₂ layer on said active area by PECVD (Plasma Enhanced Chemical Vapor Deposition);
c. depositing an amorphous capping layer on said SiO₂ layer;
d. performing an ion implantation so that said amorphous capping layer acting as a solid diffusion source;
e. performing an annealing so that dopants can be diffused into said silicon substrate and activated, and an ultra-shallow junction for nano mos devices is therefore formed;
f. removing said amorphous capping layer by wet etching technique, and said SiO₂ layer acts as an etch-stop layer to protect said ultra-shallow junction.

2. The process according to claim 1, wherein a PECVD (Plasma Enhanced Chemical Vapor Deposition) process of temperature 100^{˜}400° C. is used for forming said SiO₂ layer with thickness of 5^{˜}30 Å.

3. The process according to claim 1, wherein a LPCVD (Low Pressure Chemical Vapor Deposition) process of temperature 400^{˜}550° C. or a PECVD (Plasma Enhanced Chemical Vapor Deposition) process of temperature 100^{˜}400° C. is used for forming said amorphous layer with thickness of 100^{˜}500 Å.

4. The process according to claim 1, wherein said annealing is either an RTA (Rapid Thermal Annealing) of 800^{˜}1100° C. or a laser annealing of low temperature.

5. The process according to claim 1, wherein ions used in said ion implantation is selected from the group consisting of BF₂, B and As, with implant energy of 500^{˜}50000 eV and dosage of 10^{13˜}10¹⁶ atoms/cm².
